(19) United States
(12) Patent Application Publication
(10) Pub. No.: US 2024/0321698 A1
(43) Pub. Date: Sep. 26, 2024

(54) CHIP-ON-CHIP POWER CARD HAVING IMMERSION COOLING

(71) Applicant: Toyota Motor Engineering & Manufacturing North America, Inc., Plano, TX (US)

(72) Inventors: Feng ZHOU, Ann Arbor, MI (US); Tianzhu FAN, Houston, TX (US); Yanghe LIU, Ann Arbor, MI (US)

(73) Assignee: Toyota Motor Engineering & Manufacturing North America, Inc., Plano, TX (US)

(21) Appl. No.: 18/125,275

(22) Filed: Mar. 23, 2023

(51) Int. Cl. H01L 23/495; H01L 23/427; H01L 23/473; H01L 25/07; H02M 7/537

(52) U.S. Cl. CPC H01L 23/49568; H01L 23/427; H01L 23/473; H01L 23/49537; H01L 23/49575; H01L 25/071; H02M 7/537; H01L 23/49555; H01L 24/32; H01L 24/33; H01L 2224/32245; H01L 2224/33181; H01L 2924/10272

(57) ABSTRACT

A power card for use in a vehicle includes a plurality of chip-on-chip structures and a manifold. The chip-on-chip structures include an N lead frame, a P lead frame, an O lead frame, and a first and a second power device. The N lead frame, P lead frame, and O lead frame each have a body portion and a terminal portion extending outward from the body portion. The O lead frame is located between the N lead frame and the P lead frame. The first power device is located on a first side of the O lead frame and the second power device is located on a second side of the O lead frame. The manifold surrounds the body portions the N lead frame, the P lead frame, and the O lead frame and fluidly coupled to an inlet and an outlet, configured to receive a cooling liquid.

### TECHNICAL FIELD

The present specification generally relates to a power card having a plurality of low inductance chip-on-chip structures, and, more specifically, an apparatus and system for immersion cooling of the plurality of chip-on-chip structures.

### BACKGROUND

Modern vehicles use electricity as part of the operation of the vehicle. These vehicles may be operated using electricity exclusively, or by using a combination of electricity and another energy source. Many modern vehicles include a power control unit (PCU) configured to manage the energy amongst multiple different vehicle electrical systems. In the case of vehicles driven by electric motors, a power control unit may be used to control the electric motor, including torque and speed of the motor.

A component of the power control unit is a power card, which contains power devices that may be switched on and off in high frequency during operation of the vehicle. These power devices may generate significant amounts of heat. Conventional power cards have designs for exposing surface area of the power devices for cooling purposes. Further compact chip-on-chip power cards also include cooling devices, for example, double sided cooling by a cold plate However, the conventional power cards are bulky and not useful in compact space contexts. The inner surfaces of the chip-on-chip structure cannot be cooled with the cold plates. Thus, there is a need for a power card capable of providing cooling while being a compact size.

### SUMMARY

In one embodiment, a power card for use in a vehicle includes a plurality of chip-on-chip structures and a manifold. The chip-on-chip structures include an N lead frame, a P lead frame, an O lead frame, a first power device and a second power device. The N lead frame has a body portion and a terminal portion. The terminal portion extends outward from the body portion. The P lead frame has a body portion and a terminal portion. The terminal portion extends outward from the body portion. The O lead frame has a body portion and a terminal portion. The terminal portion extends outward from the body portion. The O lead frame is located between the N lead frame and the P lead frame. The first power device is located on a first side of the O lead frame between the body portion of the N lead frame and the body portion of the O lead frame. The second power device is located on a second side of the O lead frame between the body portion of the O lead frame and the body portion of the P lead frame. The manifold surrounds the body portion of the N lead frame, the body portion of the P lead frame, and the body portion of the O lead frame. The manifold is fluidly coupled to an inlet and an outlet, and is configured to receive a cooling liquid.

In another embodiment, a power system includes a power card and a liquid cooler. The power cark includes a plurality of chip-on-chip structures and a manifold. The chip-on-chip structures include an N lead frame, a P lead frame, an O lead frame, a first power device and a second power device. The N lead frame has a body portion and a terminal portion. The terminal portion extends outward from the body portion. The P lead frame has a body portion and a terminal portion. The terminal portion extends outward from the body portion. The O lead frame has a body portion and a terminal portion. The terminal portion extends outward from the body portion. The O lead frame is located between the N lead frame and the P lead frame. The first power device is located on a first side of the O lead frame between the body portion of the N lead frame and the body portion of the O lead frame. The second power device is located on a second side of the O lead frame between the body portion of the O lead frame and the body portion of the P lead frame. The manifold surrounds the body portion of the N lead frame, the body portion of the P lead frame, and the body portion of the O lead frame. The manifold is fluidly coupled to an inlet and an outlet, The liquid cooler is coupled to the inlet and the outlet and is configured to provide a cooling liquid to flow through the manifold and provide cooling to the power card.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a compact low inductance chip-on-chip power card, according to one or more embodiments described and illustrated herein;

FIG. 2 schematically depicts a side view of the compact low inductance chip-on-chip power card of FIG. 1, according to one or more embodiments described and illustrated herein;

FIG. 3 schematically depicts a side view of the compact low inductance chip-on-chip power card of FIG. 1, including current direction, according to one or more embodiments described and illustrated herein;

FIG. 4 schematically depicts a top side view of a 6-in-1 chip-on-chip power card, including a manifold and a flow direction of a cooling liquid, according to one or more embodiments described and illustrated herein;

FIG. 5 schematically depicts a side view of the 6-in-1 chip-on-chip power card of FIG. 4, including a manifold and a flow direction of a cooling liquid, according to one or more embodiments described and illustrated herein; and

FIG. 6 depicts a corresponding circuit diagram of the 6-in-1 chip-on-chip power card of FIGS. 4 and 5, according to one or more embodiments described and illustrated herein.

### DETAILED DESCRIPTION

Embodiments described herein are generally directed to an immersion cooling method and system to enhance the heat transfer and cooling performance of a power card with a plurality of chip-on-chip structures.

A power card may be a part of a power control unit of a vehicle. The power control unit is configured to manage the energy amongst multiple different vehicle electrical systems. In vehicles with electric motors, the power control unit may be responsible for operation of the electric motor. The power control unit may include a power card having power devices that are switched on and off at high frequencies during operations of the vehicle. These power devices may be any switch, such as an RC-IGBT, an IGBT/diode combination, or a MOSFET, for example.

The chip-on-chip power card design shows a large decrease in size and inductance compared to conventional power cards. As described in more detail below, the O lead frame, which serves as an output for one phase of the alternating current, can also be used to enhance the heat transfer from the power card to the cold plate with an embedded thermal conductor. Immersion cooling provides cooling to the internal surfaces of the chip-on-chip power card including the middle lead frame. A combination of immersion cooling and chip-on-chip power provides a higher performance and solves overheating issues.

In a power card with a plurality of the base chip-on-chip structures can perform a completed function as an inverter, with DC input and 3 phases AC output. This takes the form by combining three chip-on-chip structures. A number of chip-on-chip structures can vary based on need, for example 2 chip-on-chip structures or 6 chip-on-chip structures. The immersion liquid cooling enables advanced thermal management of the stacked chips allowing the structure to be applied for extreme high-power density applications.

The power cards described herein may be used with a vehicle. The vehicle may have an automatic or manual transmission. The vehicle may be an electric vehicle, a hybrid vehicle, a plug-in hybrid vehicle, a fuel cell vehicle, or any other type of vehicle that includes a motor/generator. Further, the vehicle may be capable of non-autonomous operation or semi-autonomous operation or autonomous operation. That is, the vehicle may be driven by a human driver or may be capable of self-maneuvering and navigating without human input. A vehicle operating semi-autonomously or autonomously may use one or more sensors and/or a navigation unit to drive autonomously.

Various embodiments of immersion cooling for chip-on-chip power card assemblies, and power systems are described in detail below. Whenever possible, the same reference numerals will be used throughout the drawings to refer to the same or like parts.

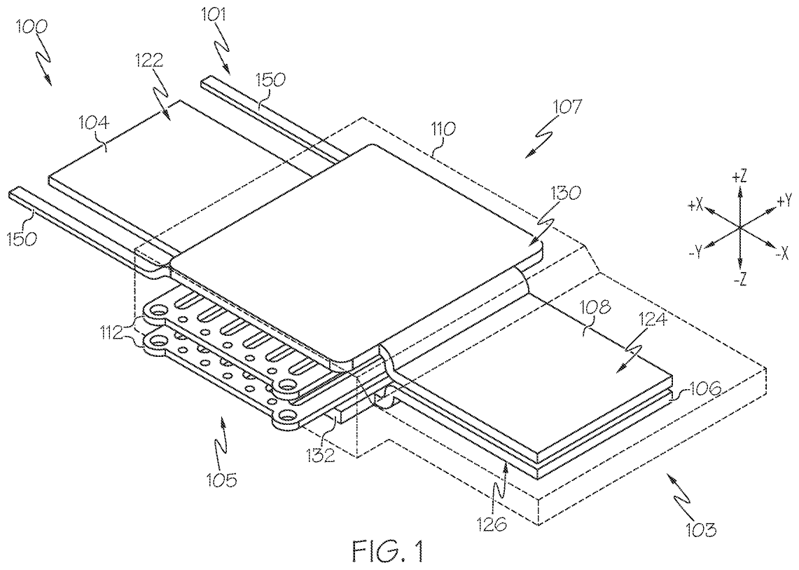

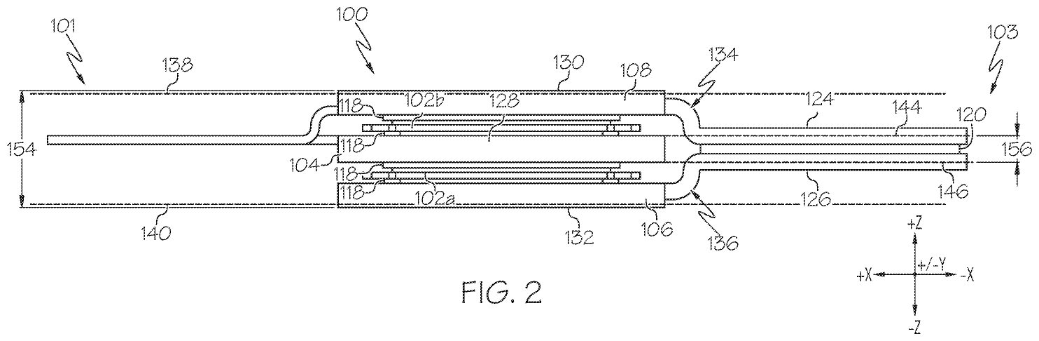

FIGS. 1 and 2 illustrates the chip-on-chip structure 100 for a power card. The chip-on-chip structure 100 has a chip-on-chip design, where the power devices 102a, 102b are located in a vertically stacked arrangement. The power card includes a P lead frame 108, a soldering layer 118, a second power device 102b, a soldering layer 118, a O lead frame 104, a soldering layer 118, a first power device 102a, a soldering layer 118, and a N lead frame 106 stacked on each other in a substantially vertical direction.

The chip-on-chip power card 100 includes the O lead frame 104 having a cooling portion 122 extending from a body portion 128 (shown in FIG. 2) towards a first end 101 of the chip-on-chip power card 100. The chip-on-chip power card 100 also includes an N lead frame 106 having a terminal portion 126 extending from a body portion 132 towards the second end 103 of the chip-on-chip power card 100. The chip-on-chip power card 100 also includes a P lead frame 108 having a terminal portion 124 extending from a body portion 130 towards the second end 103 of the chip-on-chip power card 100. The terminal portions 124, 126 are configured to connect to other vehicle components to connect the chip-on-chip power card 100 to the vehicle.

In some embodiments, the body portions of the lead frames may be referred to as the substrate. Electrical current flows from the terminal portion 124 of the P lead frame 108 to the terminal portion 126 of the N lead frame 106. The cooling portion 122 of the O lead frame 104 serves as an output. For example, when the chip-on-chip power card 100 is used in conjunction with multiple other power cards in an inverter, the terminal portion 124 of the P lead frame 108 and the terminal portion 126 of the N lead frame 106 of each power card may be connected to the DC power source, and the cooling portion 122 of the O lead frame 104 of each power card is responsible for outputting one phase of the alternating current, with the combined outputs of the terminal portions of the O lead frames of each power card creating an alternating current. The alternating current may be used to power a motor, for example. When the inverter is bi-directional, alternating current generated by regenerative braking, for example, could be received by the terminal portions of the O lead frames of the multiple power cards, and a DC battery may be recharged using the power cards.

The chip-on-chip power card 100 has a first end 101 and a second end 103 opposite the first end 101. The cooling portion 122 of the O lead frame is located at the first end 101 and the terminal portion 126 of the N lead frame and the terminal portion 124 of the P lead frame 108 are located at the second end 103. By being on opposite ends of the chip-on-chip power card 100, the terminal portions of the O lead frame 104, the N lead frame 106, and the P lead frame 108 may be as wide as the power device. In addition, by having the cooling portion 122 of the O lead frame 104 on the opposite end as the terminal portion 124 of the P lead frame 108 and the terminal portion 126 of the N lead frame 106, the terminal portion 124 of the P lead frame 108 and the terminal portion 126 of the N lead frame 106 may be located very close to each other and separated by a thin insulator. This close location to each other results in very low inductance for high-speed switching of the power devices.

The chip-on-chip power card 100 includes two sets of signal terminals 112, one set for each of the two power devices 102a, 102b. Each set of signal terminals 112 is connected to a respective power device 102a, 102b. The set of signal terminals 112 provides connections to the power device 102a, 102b, for purposes of providing switching signals to the power device 102a, 102b and also for purposes of detecting data from the power device 102a, 102b. For example, when there are 5 signal terminals in the set of signal terminals 112, one signal terminal may connected to the gate of the power device 102a, 102b and be used as a gate signal for switching the power device 102a, 102b on and off using low voltage, two signal terminals may be used for detecting temperature, one signal terminal may be used as a current sensor, and one signal terminal may be used as an emitter voltage sensor.

The chip-on-chip power card 100 also includes voltage terminals 150 as being part of the P lead frame 108. The voltage terminals 150 may be used to detect a voltage of the chip-on-chip power card 100. The voltage terminals 150 extend away from the body portion 130 of the P lead frame 108, but in a direction opposite the terminal portion 124 of the P lead frame 108. Thus, the voltage terminals 150 are located at the first end 101 of the chip-on-chip power card 100, alongside the cooling portion 122 of the O lead frame 104. The voltage terminals 150 may be located horizontally on either side of the cooling portion 122 of the O lead frame 104.

The chip-on-chip power card 100 has a first lengthwise edge 105 and a second lengthwise edge 107 opposite the first lengthwise edge 105. As shown in FIG. 1, the sets of signal terminals 112 are located at the first lengthwise edge 105 and the voltage terminals 150 are located at the first end 101. However, in some embodiments, the voltage terminals 150 may be removed and the sets of signal terminals 112 may be reduced to a single signal terminal corresponding to each power device, and these single signal terminals may be located horizontally on either side of the cooling portion 122 of the O lead frame 104, similar to the location of the voltage terminals 150 in FIG. 1.

The chip-on-chip power card 100 may be partially encased in resin 110. The resin 110 may be injection molded to the chip-on-chip power card 100 such that all gaps between the components of the chip-on-chip power card 100 are occupied with resin 110. The resin 110 may insulate the components of the chip-on-chip power card 100 to allow the chip-on-chip power card 100 to operate more efficiently. The cooling portion 122 of the O lead frame 104, the voltage terminals 150, portions of the sets of signal terminals 112, a portion of the terminal portion 124 of the P lead frame, and a portion of the terminal portion 126 of the N lead frame may not be covered in resin 110, with the remaining components of the chip-on-chip power card 100 being encased in resin 110. The exposed portion of the terminal portion 124 of the P lead frame may be the top surface of the terminal portion 124. The exposed portion of the terminal portion 126 of the N lead frame may be the bottom surface of the terminal portion 126.

FIG. 2 illustrates a side view of components of the chip-on-chip power card 100. The body portion 130 of the P lead frame 108 is aligned with the body portion 128 of the O lead frame 104 as well as the body portion 132 of the N lead frame 106. In addition, the first power device 102a is shown as being between the body portion 132 of the N lead frame 106 and the body portion 128 of the O lead frame 104. The second power device 102b is shown as being between the body portion 128 of the O lead frame 104 and the body portion 130 of the P lead frame 108. Soldering layers 118 are seen between the P lead frame 108 and the second power device 102B, between the second power device 102B and the O lead frame 104, the O lead frame 104 and the first power device 102a, and the first power device 102a and the N lead frame 106.

The terminal portion 124 of the P lead frame 108 is connected to the body portion 130 of the P lead frame 108 by a bend 134. The body portion 130 of the P lead frame lies along a P body plane 138 and the terminal portion 124 of the P lead frame 108 lies along a P terminal plane 144. The P body plane 138 and the P terminal plane 144 are parallel. The bend 134 brings the terminal portion 124 of the P lead frame 108 closer to the N lead frame 106.

The terminal portion 126 of the N lead frame 106 is connected to the body portion 132 of the N lead frame 106 by a bend 136. The body portion 132 of the N lead frame lies along an N body plane 140 and the terminal portion 126 of the N lead frame 106 lies along an N terminal plane 146. The N body plane 140 and the N terminal plane 146 are parallel. The bend 136 brings the terminal portion 126 of the N lead frame 106 closer to the P lead frame 108.

The distance 154 between the body portion 130 of the P lead frame 108 and the body portion 132 of the N lead frame 106 is greater than the distance 156 between the terminal portion 124 of the P lead frame 108 and the terminal portion 126 of the N lead frame 106 due to the bends 134, 136.

An insulator 120 may be located between the terminal portion 124 of the P lead frame 108 and the terminal portion 126 of the N lead frame 106. The voltage difference between the terminal portion 124 of the P lead frame 108 and the terminal portion 126 of the N lead frame 106 is relatively high. The insulator 120 may be configured to assist in reducing inductance between the P terminal and the N terminal. The insulator 120 may span the entire length of the terminal portion 124 of the P lead frame 108 and the terminal portion 126 of the N lead frame 106, or may occupy a portion thereof. The insulator 120 may be made of ceramic or any other insulating material. The insulator 120 may be very thin-approximately 320 μm thick. The insulator 120 may occupy the entire distance 156 between the terminal portion 124 of the P lead frame 108 and the terminal portion 126 of the N lead frame 106.

The body portion 128 of the O lead frame 104 has a top surface that lies along an O plane 142. The cooling portion 122 of the O lead frame 104 may also lie along the O plane 142 such that a top surface of the body portion 128 of the (lead frame is coplanar to a top surface of the cooling portion 122 of the O lead frame 104.

The voltage terminals 150 of the P lead frame 108 may extend in a direction opposite the terminal portion 124 of the P lead frame 108. The voltage terminals 150 may be connected to the body portion 130 of the P lead frame 108 by a bend, and the voltage terminals 150 may lie along the O plane 142.

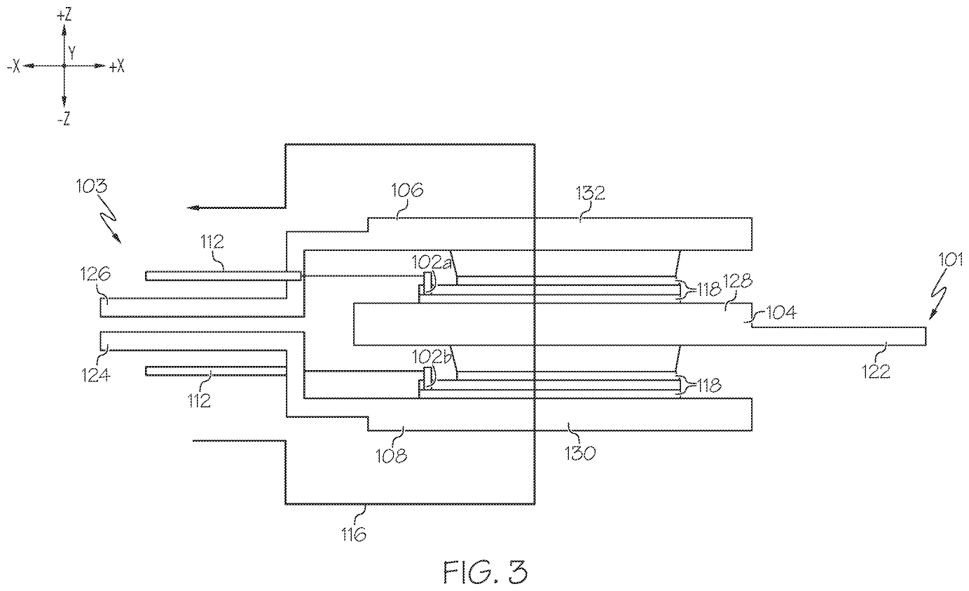

FIG. 3 depicts the compact low inductance chip-on-chip power card 100 with the embedded copper-graphite thermal conductor 109 and the electrical current 116 direction. The electrical current 116 travels from the terminal portion 124 of the P lead frame 108 through body portion 130 of the P lead frame 108 and through the two power devices 102a, 102b. The electrical current then flows through the body portion 132 of the N lead frame 106 and into the terminal portion 126 of the N lead frame 106. The electrical current 116 travels in strait line through the chip-on-chip power card 100, making the chip-on-chip power card 100 more efficient than traditional power cards. Electrical current 116 flows from the P lead frame 108 to the power devices 102a, 102b, and through the N lead frame 106. The O lead frame 104 serves as an output.

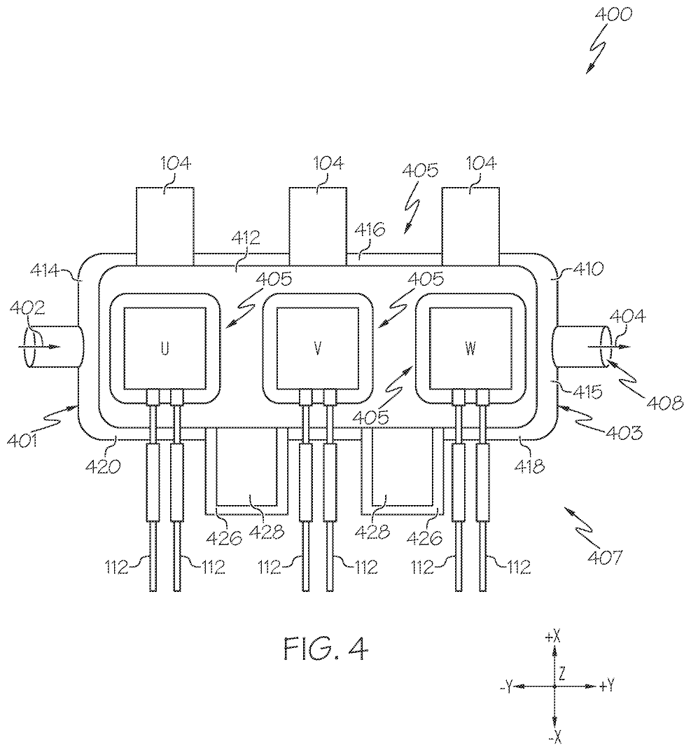

Now looking at FIG. 4, a top side view of a 6-in-1 chip-on-chip power card 400, including a manifold 410 and a flow direction of a cooling liquid is illustrated. The 6-in-1 Chip-On-Chip Power Card 400 includes a plurality of chip-on-chip structures 405 U, V, and W. Each of the plurality of chip-on-chip structures 405 include a O lead frame 104, a P lead frame 108 and an N lead frame 106. Each of the plurality of chip-on-chip structures 405 also includes a set of signal terminals 112. In embodiments, additional chip-on-chip structures 405 may be added. Each of the chip-on-chip structures 405 generally include the features as described above in the chip-on-chip power card 100.

A manifold 410 surrounds the body portion 130 of the P lead frame 108, the body portion 128 of the O lead frame 104, and the body portion 132 of the N lead frame. The manifold includes an inlet 402 and an outlet 404 to allow for a cooling liquid 408 to flow into the inlet 402, through the manifold 410, and out the outlet 404. The manifold includes a first end 401 and an opposite second end 404. The manifold further includes a first side wall 414, a second side wall 415 opposite the first side wall 414, a front side wall 416 and a back side wall 418 opposite the front side wall 416, the front side wall 416 and the back side wall 418 extending between the first side wall 414 and the second side wall 415, a top side wall 412 and a bottom side wall 420 opposite the top side wall 412 and extending between the first side wall 414 and the second side wall 415 and the front side wall 416 and the back side wall 416. The first side wall 415, the second side wall 415, the front side wall 416, the back side wall 418, the top side wall 412 and the bottom side wall 420 are coupled as to encase the body portion 128 of the O lead frame 104, and the body portion 132 of the N lead frame 106 and surround a lengthwise periphery of the body portion 128 of the O lead frame 104, and the body portion 132 of the N lead frame 106.

The inlet 402 is located in the first side wall 414 at the first end 401 of the manifold 410 and the outlet 404 is located in the second side wall 415 at the second end 403 of the manifold 410. The inlet 402 and outlet 404 are configured to allow a cooling liquid 408 to flow through the manifold 410. However, it should be understood that the inlet 402 and outlet 404 may be located on any of the first side wall 414, second side wall 415, front side wall 416, back side wall 418, top side wall 412 and bottom side wall 420 as to allow the cooling liquid 408 to flow through the manifold 410.

Each of the chip-on-chip structures 405 located in the 6-in-1 chip-on-chip power card 400 include an O lead frame 104 that extends out of the front side wall 416 of the manifold 410. The manifold 410 is sealed around the O lead frames 104 as to prevent the cooling liquid 408 from leaking. Further, each of the chip-on-chip structures 405 located in the 6-in-1 chip-on-chip power card 400 includes a set of terminals 112 and a connection to P terminals 428 and N terminals 426 extending out from the back side wall 418 of the manifold. The manifold 410 is sealed around the sets of terminals 112, the P terminals 428 and the N terminals 426 as to prevent the cooling liquid 408 from leaking. The P terminals 428 connect to the P lead frame 108 of each of the plurality of chip-on-chip structures 405. The N terminals 428 connect to the N lead frame 106 of each of the plurality of chip-on-chip structures 405.

In embodiments, the manifold 410 may be configured to receive a cooling liquid 408 for single phase immersion cooling. That is, a single liquid flows through the manifold 410 from the inlet 402 to the outlet 404 and absorbs heat from each surface of the chip-on-chip structure 405 that is within the manifold 410. These surfaces include, but are not limited to the O lead frame 104, the bottom surfaces of the P lead frame 108 and the N lead frame 106, the sides of the chip, the sides of the solder, and the sides of each lead frame. Further, in embodiments, in the 6-in-1 chip-on-chip power card 400 with immersion cooling, no other thermal resistance, or grease layers, exist between the chip and the cooling liquid 408. In embodiments, the plurality of chip-on-chip structures 405 may include small pins, dimples, extrusions, surface roughness on the O lead frame 104, the P lead frame 108, and the N lead frame 106 to enhance the heat transfer and create a higher heat transfer coefficient.

In some embodiments, the cooling liquid 408 is a dielectric coolant, in these embodiments, no insulation layer is needed between the chip-on-chip structure 405 surfaces and the cooling liquid. In other embodiments, the cooling liquid 408 may be a non-dielectric coolant. In these embodiments, an electrical insulation material is deposited on all the surfaces between the chip-on-chip structure 405 and the non-dielectric coolant. In these embodiments, the non-dielectric may be a water-ethylene glycol. In embodiments, the electrical insulation material is a material produced by chemical vapor deposition (CVD), for example, the electrical insulation material may be Si₃N₄, AlN, SiO₂, and the like.

In other embodiments, the manifold 410 may be configured for two phase immersion cooling. In these embodiments, the cooling liquid may be a mineral oil, fluorocarbons, perfluorocarbons or the like. Further, in such embodiments, porous media may be added to the chip-on-chip structure 405 surfaces to enhance the two-phase cooling.

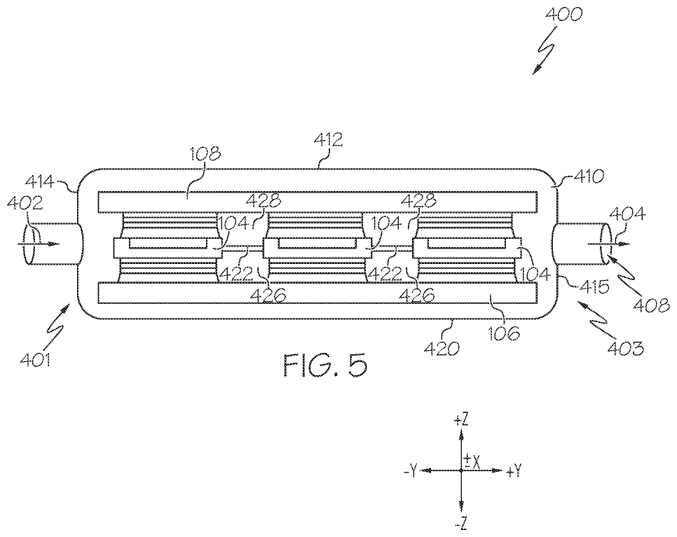

Now referring to FIG. 5, a side view of the 6-in-1 chip-on-chip power card 400 is depicted. The P lead frame 108 and the N lead frame 106 are seen connected to each of the chip-on-chip structures 405. A ceramic insulator 422 is located between the P terminal 428 and the N terminal 426. The cooling liquid 408 flows into the inlet 408, absorbs the heat from the internal surfaces in the manifold 410, and exits the outlet. In embodiments, the cooling liquid 408 flows at a rate between 5 liters per minute and 15 liters per minute. In other embodiments the cooling liquid flows at a rate between 8 liters per minute and 12 liters per minute. However, it should be understood that the cooling liquid 408 may flow at any rate appropriate to the material.

In a embodiments, the 6-in-1 chip-on-chip power card 400 may be a SIC Mos with 500 Watts applied. In such embodiments the maximum temperature is under 130 degrees C. with a 30,000 W/(m²K) immersion cooling heat transfer coefficient. However, it should be understood that the immersion cooling may be a different value depending on flow rate, power card structure, the type of cooling liquid, and the amount of phases. For example, a single-phase immersion cooling at a low flow rate with dielectric coolant would have a lower heat transfer coefficient.

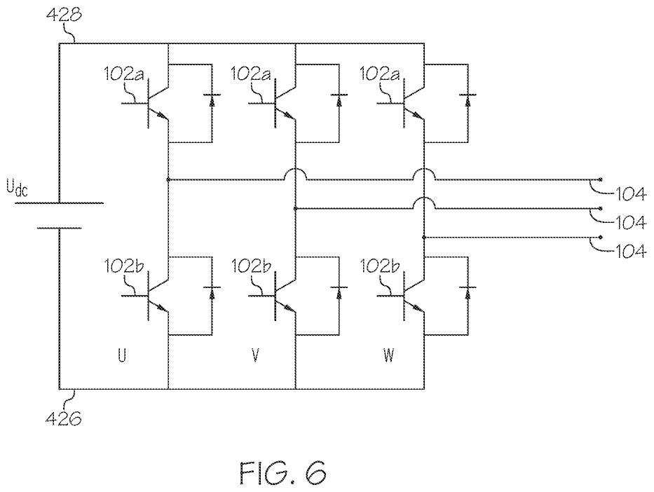

Now looking at FIG. 6, the corresponding circuit of the 6-in-1 chip on chip power card is illustrated. In the circuit, the each of the chip-on-chip structures U, V, W are connected to the one N terminal 426 and the one P terminal 428. Further we see the power devices 102a and 102b as described above. Each chip-on-chip structure U, V, and W has an output of the O lead frame 104. In embodiments, the 6-in-1 chip-on-chip power card 400 can perform a completed function as an inverter, with DC input and three phases AC output. Combined with the manifold and immersion liquid cooling, the 6-in-1 power card 400 can be applied for extreme high power-density applications.

From the above, it is to be appreciated that defined herein are power systems and assemblies. Specifically, the power systems with a power card assembly disclosed herein include a power card with a plurality of chip-on-chip structures, wherein the structures are located in a substantially vertical stacked arrangement of a P lead frame, a soldering layer, a power device, a soldering layer, a O lead frame, a soldering layer, a power device, a soldering layer, and a N lead frame. The power card, having a plurality of chip-on-chip structures, includes an immersion cooling method and system to enhance the heat transfer and cooling performance of the power card.

It should now be understood that embodiments of the present disclosure are directed to an immersion cooling method and system to enhance the heat transfer and cooling performance of a power card with a plurality of chip-on-chip structures configured to manage the energy amongst multiple different vehicle electrical systems.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

What is claimed is:

1. A power card for use in a vehicle, the power card comprising:
a plurality of chip on chip structures, each having:
an N lead frame having a body portion and a terminal portion, the terminal portion extending outward from the body portion;
a P lead frame having a body portion and a terminal portion, the terminal portion extending outward from the body portion;
an O lead frame having a body portion and a terminal portion, the terminal portion extending outward from the body portion, the O lead frame being located between the N lead frame and the P lead frame;
a first power device being located on a first side of the O lead frame between the body portion of the N lead frame and the body portion of the O lead frame; and
a second power device being located on a second side of the O lead frame between the body portion of the O lead frame and the body portion of the P lead frame,
a manifold surrounding the body portion of the N lead frame, the body portion of the P lead frame, and the body portion of the O lead frame, the manifold being fluidly coupled to an inlet and an outlet, the manifold configured to receive a cooling liquid.

2. The power card of claim 1, wherein the manifold is configured to receive a cooling liquid for single-phase immersion cooling.

3. The power card of claim 1, wherein the manifold is configured to receive a cooling liquid for two-phase immersion cooling.

4. The power card of claim 1, wherein the cooling liquid is a dielectric coolant.

5. The power card of claim 1, wherein
an electrical insulation material is deposited on surfaces of the plurality of chip-on-chip structures in contact with the cooling liquid; and
the cooling liquid is a non-dielectric coolant.

6. The power card of claim 3, wherein surfaces of the power card contain porous media.

7. The power card of claim 1, wherein the P lead frame, O lead frame and N lead frame contain at least one of small pins, dimples, extrusions, or surface roughness.

8. The power card of claim 1, wherein the cooling liquid flows from the inlet to the outlet of the manifold at a flow rate between 8 liters per minute and 12 liters per minute.

9. The power card of claim 1, wherein the power card contains three chip-on-chip structures.

10. The power card of claim 1, wherein the manifold surrounds a lengthwise periphery of the body portion of the N lead frame, the body portion of the P lead frame, and the body portion of the O lead frame.

11. A power system comprising,
a power card comprising a plurality of chip-on-chip structures and a manifold, the chip-on-chip structures comprising:
an N lead frame having a body portion and a terminal portion, the terminal portion extending outward from the body portion;
a P lead frame having a body portion and a terminal portion, the terminal portion extending outward from the body portion;
an O lead frame having a body portion and a terminal portion, the terminal portion extending outward from the body portion, the O) lead frame being located between the N lead frame and the P lead frame;
a first power device being located on a first side of the O lead frame between the body portion of the N lead frame and the body portion of the O lead frame; and
a second power device being located on a second side of the O lead frame between the body portion of the O lead frame and the body portion of the P lead frame, wherein
the manifold surrounds the body portion of the N lead frame, the body portion of the P lead frame, and the body portion of the O lead frame, the manifold fluidly coupled to an inlet and an outlet, and
a liquid cooler coupled to the inlet and the outlet configured to provide a cooling liquid to flow through the manifold and provide cooling to the power card.

12. The power system of claim 11, wherein the manifold is configured to receive a cooling liquid for single-phase immersion cooling.

13. The power system of claim 11, wherein the manifold is configured to receive a cooling liquid for two-phase immersion cooling.

14. The power system of claim 11, wherein the cooling liquid is a dielectric coolant.

15. The power system of claim 11, wherein
an electrical insulation material is deposited on surfaces of the plurality of chip-on-chip structures in contact with the cooling liquid; and
the cooling liquid is a non-dielectric coolant.

16. The power system of claim 13, wherein surfaces of the power card contain porous media.

17. The power system of claim 11, wherein the P lead frame, O lead frame and N lead frame contain at least one of small pins, dimples, extrusions, or surface roughness.

18. The power system of claim 11, wherein the cooling liquid flows from the inlet to the outlet of the manifold at a flow rate between 8 liters per minute and 12 liters per minute.

19. The power system of claim 11, wherein the power card contains three chip-on-chip structures.

20. The power system of claim 11, wherein the liquid cooler is coupled to a vehicle device and configured to provide the cooling liquid to the vehicle device.
